(19) United States
(12) Patent Application Publication
(10) Pub. No.: US 2021/0185793 A1
(43) Pub. Date: Jun. 17, 2021

(54) ADHESIVE MATERIAL REMOVAL FROM PHOTOMASK IN ULTRAVIOLET LITHOGRAPHY APPLICATION

(71) Applicant: Applied Materials, Inc., Santa Clara, CA (US)

(72) Inventors: Banqiu WU, San Jose, CA (US); Khalid MAKHAMREH, Los Gatos, CA (US); Eli DAGAN, Sunnyvale, CA (US)

(21) Appl. No.: 16/714,247

(22) Filed: Dec. 13, 2019

(51) Int. Cl. H05H 1/24; G03F 1/82

(52) U.S. Cl. CPC H05H 1/2406; H05H 2001/2437; H05H 2001/2412; G03F 1/82

(57) ABSTRACT

Embodiments of the present disclosure generally provide apparatus and methods for removing an adhesive material from a photomask. In one embodiment, an apparatus for processing a photomask includes an enclosure, a substrate support assembly disposed in the enclosure, and a dielectric barrier discharge (DBD) plasma generator disposed above the substrate support assembly, wherein the dielectric barrier discharge plasma generator further comprises a first electrode, a second electrode, wherein the first and the second electrodes are vertically aligned and in parallel, a dielectric barrier positioned between the first electrode and the second electrode, and a discharge space defined between the dielectric barrier and the second electrode.

### BACKGROUND

### Field

Embodiments of the present disclosure generally relate to methods and apparatus for an adhesive layer removal process from a photomask. Particularly, embodiments of the present disclosure provide methods and apparatus for an adhesive layer removal process after a pellicle removal process on a photomask using a dielectric barrier discharge plasma process.

### Description of the Related Art

In the manufacture of integrated circuits (IC), or chips, patterns representing different layers of the chip are created by a chip designer. A series of reusable masks, or photomasks, are created from these patterns in order to transfer the design of each chip layer onto a semiconductor substrate during the manufacturing process. Mask pattern generation systems use precision lasers or electron beams to image the design of each layer of the chip onto a respective mask. The masks are then used much like photographic negatives to transfer the circuit patterns for each layer onto a semiconductor substrate. These layers are built up using a sequence of processes and translate into the tiny transistors and electrical circuits that comprise each completed chip. Thus, any defects in the mask may be transferred to the chip, potentially adversely affecting performance. Defects that are severe enough may render the mask completely useless. Typically, a set of 15 to 30 masks is used to construct a chip and can be used repeatedly.

The increasing circuit densities have placed additional demands on processes used to fabricate semiconductor devices. For example, as circuit densities increase, the widths of vias, contacts and other features, as well as the dielectric materials between them, decrease to sub-micron dimensions, whereas the thickness of the dielectric layers remains substantially constant, with the result that the aspect ratios for the features, i.e., their height divided by width, increases. Reliable formation of high aspect ratio features is important to the success of sub-micron technology and to the continued effort to increase circuit density and quality of individual substrates.

Photolithography is a technique used to form precise patterns and structures on the substrate surface and then the patterned substrate surface is etched to form the desired device or features. The photolithographic technique utilizes a photolithographic substrate, such as a reticle, which has corresponding configures of features desired to be transferred to a target substrate, such as a semiconductor wafer. A light source emitting ultraviolet (UV) light or deep ultraviolet (DUV) light is transmitted through the photomask substrate to expose photoresist disposed on the substrate. Generally, the exposed resist material is removed by a chemical process to expose the underlying substrate material. The exposed underlying substrate material is then etched to form the features in the substrate surface while the retained resist material remains as a protective coating for the unexposed underlying substrate material.

Typically, one photomask, e.g., a reticle, may be repeatedly used to reproducibly print thousands of substrates. Typically, a photomask, e.g., a reticle, is typically a glass or a quartz substrate giving a film stack having multiple layers, including a light-absorbing layer and an opaque layer disposed thereon. While performing the photolithography process, a pellicle is used to protect the reticle from particle contamination. Pellicle is a thin transparent membrane which allows lights and radiation to pass therethrough to the reticle. Pellicles provide a functional and economic solution to particulate contamination by mechanically separating particles from the mask surface. After the photomask has been used for a number of cycles and the pellicle has become damaged or too dirty to use, the photomask is removed and the pellicle replaced.

Pellicles are typically supported and held on the reticle by an adhesive material, such as glue. However, when replacing the pellicle and the attachment feature from the photomask, residual adhesive material is often difficult to be removed from the reticle. Aggressive mechanical cleaning often results in reticle damage, surface roughness, or film stack and/or structure damage of the photomask.

Therefore, there is a need for apparatus and methods for removing or cleaning adhesive material from the attachment feature on the reticle after periodic use.

### SUMMARY

Embodiments of the present disclosure generally provide apparatus and methods for removing an attachment feature, particularly for adhesive materials in the attachment feature, from a photomask. In one embodiment, an apparatus for processing a photomask includes an enclosure, a substrate support assembly disposed in the enclosure, and a dielectric barrier discharge (DBD) plasma generator disposed above the substrate support assembly, wherein the dielectric barrier discharge plasma generator further comprises a first electrode, a second electrode, wherein the first and the second electrodes are vertically aligned and in parallel, a dielectric barrier positioned between the first electrode and the second electrode, and a discharge space defined between the dielectric barrier and the second electrode.

In another embodiment, a method for processing a photomask includes removing an adhesive material from a photomask by a plasma generated from a dielectric barrier discharge plasma generator.

In yet another embodiment, a method for processing a photomask includes applying a power in a dielectric barrier discharge plasma generator disposed in an enclosure, directing a discharge gas in a discharge space defined in the dielectric barrier plasma generator to a surface of a photomask disposed in a substrate support assembly in the enclosure, generating a plasma in the discharge space toward the surface of the photomask, and removing an adhesive material on the photomask.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 schematically illustrates a lithography system in accordance with one embodiment of the present disclosure.

FIG. 2 schematically illustrates a cross sectional view of a photomask that may be used in the lithography system of FIG. 1.

FIG. 3A schematically illustrates a cross sectional view of the photomask of FIG. 2 after pellicle is removed from the photomask.

FIG. 3B illustrates a top view of the photomask of FIG. 2 after pellicle is removed from the photomask.

FIG. 4 depicts a flow diagram of an adhesive material removal process for removing an adhesive material from a reticle.

FIG. 5 illustrates cross sectional views of the photomask during different stages of the removal process of FIG. 4.

FIG. 6 depicts a cross sectional view of a photomask after an adhesive material is removed from the photomask.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally provide apparatus and methods for removing an adhesive material in an attachment feature utilized to hold a pellicle from a photomask. The attachment feature is utilized to hold and/or support a pellicle to the photomask. The attachment feature includes an adhesive material attached between the pellicle and the photomask. An adhesive material removal apparatus is utilized to remove the adhesive material from the photomask. In one example, an adhesive material removal apparatus includes a dielectric barrier discharge (DBD) plasma generator that may generate plasma to react with the adhesive material, thus enabling removal of the adhesive material from the photomask. In one example, the dielectric barrier discharge (DBD) plasma may be performed in suitable pressure range, including under an atmospheric pressure (AP).

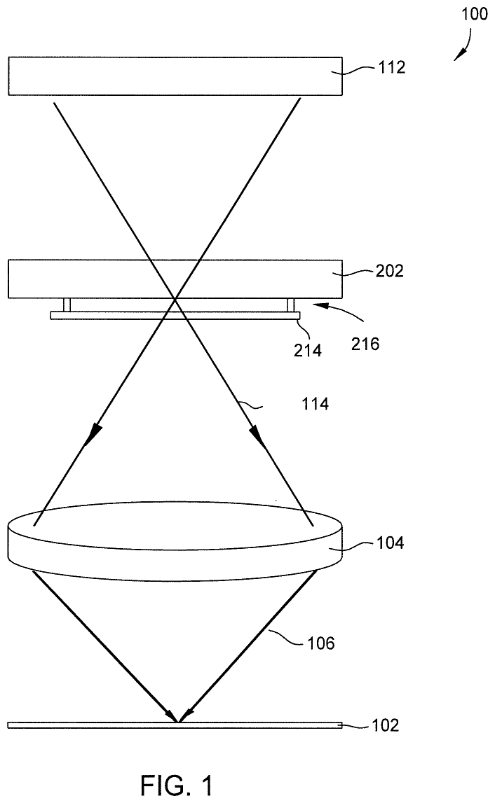

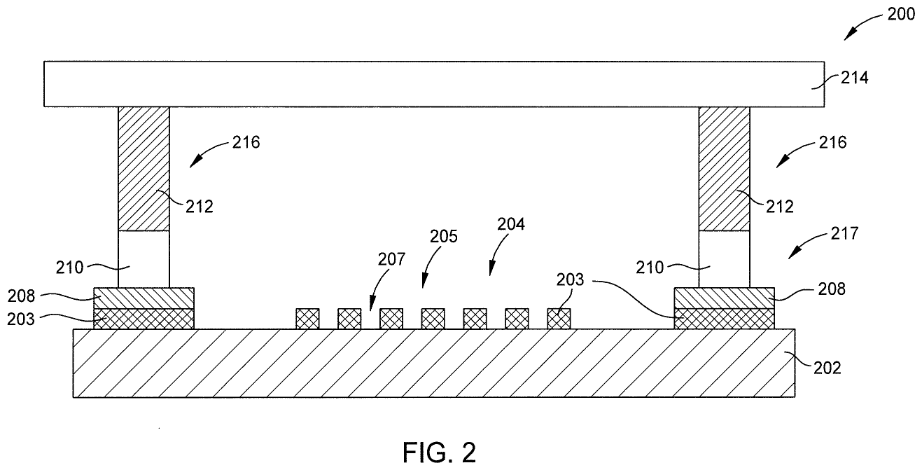

FIG. 1 depicts a photolithographic system 100. The photolithographic system 100 includes a light source 112 providing an initial patterning radiation 114 through a back of a photomask (e.g., reticle) 202. The initial patterning radiation 114 further passes through a projection lens 104, providing a final patterning radiation 106 to a surface of a substrate 102, such as a semiconductor substrate. The substrate 102 may have a photoresist layer (not shown) to assist exposing into a photoresist layer. The photomask 202 includes a pellicle 214 supported by an attachment fixture 216. A pellicle 214 may be used to protect the surface of the photomask 202 from particle contamination or other sources of contamination while processing. The pellicle 214 may be supported by the attachment fixture 216 at a predetermined location 217, such as a periphery region, of the photomask 202. The pellicle 214 and the attachment fixture 216 may be removable and replaceable from the photomask 202. The attachment fixture 216 may have an adhesive material to assist attach the attachment fixture 216 to the photomask 202. Details of the attachment fixture 216 and the film stack formed on the photomask 202 will be further described in FIG. 2. The adhesives layer from the attachment fixture 216 along with the pellicle 214 may be typically fabricated from polymers or plastic materials with additives and/or solvents. As the pellicle 214 and adhesives material are exposed to radiation or light from the light source 112, the material of the pellicle 214, adhesive and solvents may outgas or evaporate, producing one or more types of residual organic compounds. The outgassed organic compounds may further reduce pellicle transparency, cause pellicle thinning and accelerate pellicle photo-degradation.

Furthermore, after a number of process has been performed and the pellicle 214 and the attachment fixture 216 is removed from the photomask 202, some residual adhesive compounds may remain on the periphery region 217 of the photomask 202 where the attachment fixture 216 was supported, which often requires additional cleaning or adhesive removal process to remove the adhesive materials or compounds from the photomask 202.

FIG. 2 depicts details of a film stack 204 disposed on the photomask 202, such as a reticle. The photomask 202 includes a film stack 204 disposed on the photomask 202 having desired features formed therein. In the exemplary embodiment depicted in FIG. 2, the photomask 202 may be a quartz substrate (i.e., low thermal expansion silicon dioxide (SiO₂)). The photomask 202 has a rectangular shape having sides between about 5 inches to about 9 inches in length. The photomask 202 may be between about 0.15 inches and about 0.25 inches thick. In one embodiment, the photomask 202 is about 0.25 inches thick.

The film stack 204 includes features 207 formed therein. The film stack 204 is formed in a center region 205 and a periphery region 217. It is noted that the features 207 and the film stack 204 depicted in FIGS. 2, 3A-3B and 5-6 are only for illustration purpose so that the features 207 and the film stack 204 may be in any form as needed. The film stack 204 includes an absorber layer 208 disposed on a phase shift layer 203. The absorber layer 208 may be a metal containing layer, e.g., a chromium containing layer, such as a Cr metal, chromium oxide (CrOₓ), chromium nitride (CrN) layer, chromium oxynitride (CrON), or multilayer with these materials, as needed. The phase shift mask layer 203 may be a molybdenum containing layer, such as Mo layer, MoSi layer, MoSiN, MoSiON, and the like. It is noted that the absorber layer 208 is predominately remained in the predetermined location, such as the periphery region 217, of the photomask 202 so as to allow the attachment fixture 216 to be disposed thereon. The film stack 204 in the center region 205 of the photomask 202 predominately includes the phase shift mask layer 203.

In the periphery region 217 of the photomask 202, the attachment fixture 216 is formed thereon to support the pellicle 214, as shown in FIG. 2. The attachment fixture 216 includes a pellicle frame 212 utilized to hold the pellicle 214 and an adhesive material 210, such as a pellicle glue ring, utilized to assist attaching the pellicle frame 212 to the photomask 202. The pellicle frame 212 may be made of any suitable material, such as metal containing materials, conductive materials, plastic materials, dielectric materials, or other materials suitable to hold the pellicle 214. In one example, the pellicle frame 212 is a conductive material selected from a group consisting of titanium, aluminum, stainless steel, combinations thereof and alloys thereof. The adhesive material 210 may be any suitable glue layer, such as acrylic glue. The interface between the pellicle frame 212 and the pellicle 214 may include chemical adherence mechanical clamping mechanism to assist attaching the pellicle 214 securely on the pellicle frame 212 as needed.

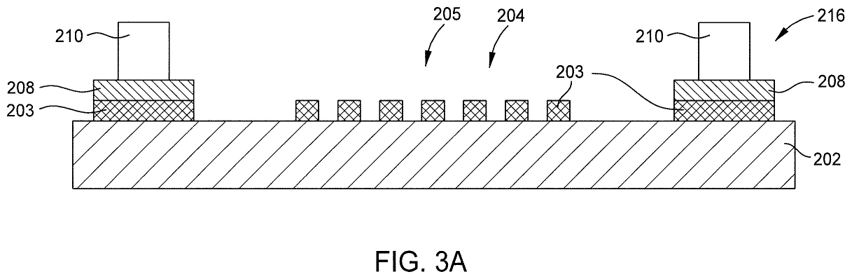

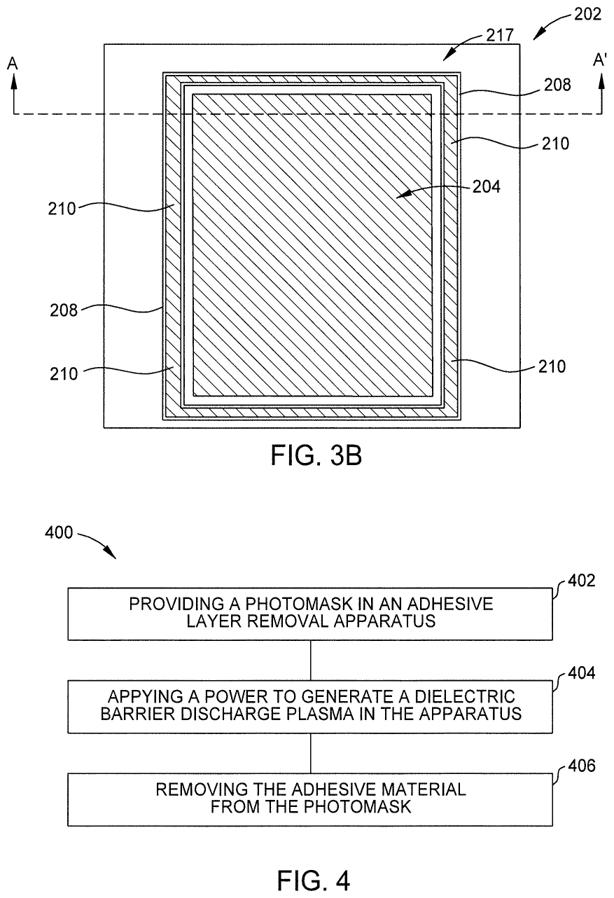

Prior to the adhesive material removal process depicted in FIG. 4, the pellicle 214 and the pellicle frame 212 may be removed from the attachment fixture 216, as shown in FIG. 3A, by any suitable manner or mechanism. FIG. 3B depicts a top view of the photomask 202. FIG. 3A depicts the cross sectional view along the cutting line A-A′ shown in FIG. 3B. The attachment fixtures 216 are located at the periphery region 217 of the photomask 202. As the pellicle frame 212 has been removed from the photomask 202, the example depicted in FIG. 3B merely includes the adhesive material 210 remained on the absorber layer 208 disposed in the periphery region 217 of the photomask 202.

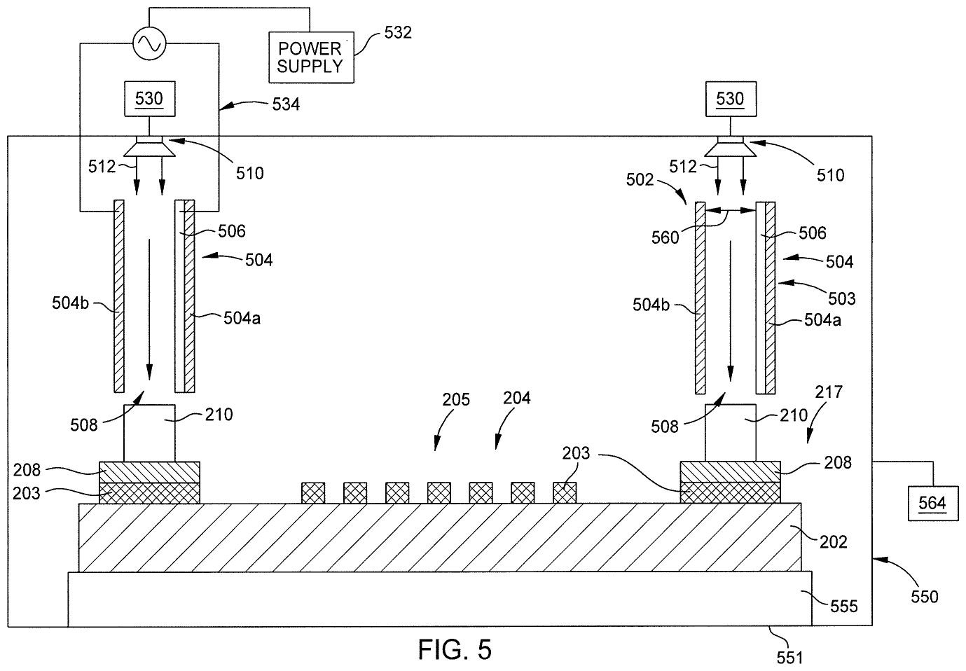

FIG. 4 depicts an adhesive material removal process 400 that may be utilized to remove the adhesive material 210 from the photomask 202. FIG. 5 depicts cross sectional views of the photomask 202 in an adhesive material removal apparatus 550.

The adhesive material removal process 400 starts at operation 402 by providing the photomask 202 in an adhesive material removal apparatus, such as the adhesive material removal apparatus 550 depicted in FIG. 5. The adhesive material removal apparatus 550 may provide an enclosure 551 that has a dielectric barrier discharge (DBD) plasma generator 503. The adhesive material removal apparatus 550 is configured to remove the adhesive material 210 from the photomask 202. The configuration (e.g., profile, shape, and/or contour) of the dielectric barrier discharge (DBD) plasma generator 503 may be in any profile or shape as needed to efficiently remove the adhesive material 210 from the photomask 202. In the embodiment depicted herein, the dielectric barrier discharge (DBD) plasma generator 503 may have electrodes formed in rectangular shape/configuration to efficiently remove the adhesive material 210 (e.g., located at periphery region 217 of the photomask 202 in a rectangular arrangement as shown in FIG. 3B) disposed on the photomask 202.

At operation 404, a power is applied to the dielectric barrier discharge (DBD) plasma generator 503 disposed in the adhesive material removal apparatus 550 to generate a plasma. In one embodiment, the dielectric barrier discharge (DBD) plasma generator 503 includes a pair of electrodes 504, such as a first electrode 504a and a second electrode 504b disposed in parallel and vertically aligned and a dielectric barrier 506 disposed against the first electrode 504a. The first electrode 504a may be grounded. The electrodes 504 are attached to but insulated from the enclosure 551 (insulation not shown in the Figures). The dielectric barrier 506 is disposed between the first electrode 504a and the second electrode 504b defining an opening 508 (e.g., a discharge space) between the first and the second electrodes 504a, 504b. The dielectric barrier 506 also maintains the first electrode 504a and the second electrode 504b in a spaced-apart relation. Though the example depicted in FIG. 5 shows the dielectric barrier 506 is disposed against the first electrode 504a, it is noted that the position of the dielectric barrier 506 may also be adjusted or changed to other positions, such as against the second electrode 504b, as needed.

In one example, the first and the second electrodes 504a, 504b are an electrical conductive material that may generate electronic field when applying a power thereto. Suitable materials of the first and the second electrodes 504a, 504b include, but not limited to, aluminum, stainless steel, tungsten, copper, molybdenum, nickel, and other metal material.

Furthermore, in one embodiment, the first electrode 504a may be a conductive material as described above and coated with a dielectric layer to form the dielectric barrier 506. Suitable materials of the dielectric layer include, but not limited to MgO, SiO₂, Y₂O₃, La₂O₃, CeO₂, SrO, CaO, MgF₂, LiF₂, and CaF₂, among others. The conductive material could be indium tin oxide (ITO), SnO₂, W, Mo, Cu, aluminum, alloys thereof, or another metal.

The dielectric barrier 506 acts as a current limiter during plasma generation process so as to assist generating plasma in a discharge gas supplied into the opening 508. In one embodiment, the dielectric barrier 506 is a transparent dielectric material such as glass, quartz, ceramics, polymer materials or other suitable materials.

The opening 508 defined between the first and the second electrodes 504a, 504b is a discharge space that allows the discharge gas to be supplied thereto. A gas outlet 510 is coupled to a gas source 530 configured to supply the discharge gas into the opening 508. The gas outlet 510 is disposed at a predetermined angle so as to inject the discharge gas predominately in the opening 508 defined between the first and the second electrodes 504a, 504b. As a result, the center region 205 where the phase shift mask layer 203 is disposed on the photomask 202 would not be affected, reacted, or damaged by the discharge gas supplied into the adhesive material removal apparatus 550 during the adhesive material removal process. The gas outlet 510 is configured to continuously supply gas into the opening 508 so as to allow the plasma generated in the opening 508 to align with a location where the adhesive material 210 is formed on the photomask 202. Similarly, the configuration of the electrodes 504 is also selected so as to confine the first and the second electrodes 504a, 504b in a manner that allows the plasma as generated to be flown in a direction toward the adhesive material 210 on the photomask, rather than the center region 205 of the film stack 204 on the photomask 202, so as to dominantly react with the adhesive material 210 on the photomask without damaging other areas of the photomask 202, including the absorber layer 208 disposed underneath the adhesive material 210.

In one example, the opening 508 (e.g., the discharge space) has a selected discharging distance 560 (e.g., a width) creating a discharge volume to allow sufficient collisions among the electrons and the discharge gas executed in the opening 508. The discharge volume is configured to sufficiently promote the collisions of the electrons and the discharge gas so that excited species, including excimers, may be created, therefore, generating the plasma as desired. In one embodiment, the discharging distance 560 of the opening 508 (e.g., the discharge space) is selected within an adequate range to promote the collisions in the opening 508. In another embodiment, the discharging distance 560 of the opening 508 is selected between about 5 mm and about 50 mm, such as between about 10 mm and about 20 mm, for example, between about 2 mm and about 30 mm.

The collision of electrons with the discharge gas provides energy to the discharge gas creating reactive species including discharge plasma species and excimers. Such discharge plasma species and excimers reach to the adhesive material 210 disposed on the photomask 202, activating the adhesive material 210 so as to soften and react with the adhesive material 210, which may be removed from the photomask 202 in volatile state, or by further mechanical cleaning/scrubbing after the adhesive material removal process.

In one embodiment, the discharge gas may be oxygen gas (O₂), a hydrogen gas (H₂), or a nitrogen gas (N₂). In another embodiment, the discharge gas may be a gas mixture selected from a group including noble gases, such as xenon gas (Xe), krypton gas (Kr), argon gas (Ar), neon gas (Ne), helium gas (He) and the like. In yet another embodiment, the discharge gas may be a gas mixture including at least one of oxygen gas (O₂), a hydrogen gas (H₂), a nitrogen gas (N₂), a noble gas, a halogen containing gas, such as fluorine, bromine and chlorine gas, H₂O, NH₃, the combinations thereof, or the like.

A circuit arrangement 534 applies an operating voltage from a power supply 532 to the first electrode 504a and the second electrode 504b. In operation, the voltage applied to the two electrodes 504a, 504b establishes an electric field that promotes the electrons being collided in the opening 508. The electron collision generates energy to the discharge gas in the opening 508, thus energizing the discharge gas into an excited state, forming a plasma, which often includes reactive species, discharge species, or excimers. The plasma promotes reaction between the reactive species from the plasma selective to the adhesive material 210 and relatively inert to the underlying absorber layer 208, thus efficiently removing the adhesive material 210 from on the surface of the photomask 202 without damaging the underlying absorber layer 208. In one example, the voltage applied by the circuit arrangement 534 from the power supply 532 is selected so that an electric field may be established that is sufficient to generate a plasma as described above. In one embodiment, the voltage may be applied between about 100 Volts or about 20,000 Volts.

An atmosphere control system 564 is coupled to the enclosure 551. The atmosphere control system 564 includes throttle valves and pumps for controlling chamber pressure. The atmosphere control system 564 may additionally include gas sources for providing process or other gases to the interior volume of the adhesive material removal apparatus 550. In one embodiment, the atmosphere control system 564 may assist controlling the pressure at a desired range during the adhesive material removal process. In one example, the pressure during the adhesive material removal process may be controlled at atmospheric pressure, such as at ambient pressure wherein the photolithographic system 100 is located.

During the operation 404, a frequency of power supply between about 100 KHz and about 3 GHz may be applied to the dielectric barrier discharge (DBD) plasma generator 503 to generate a plasma in the opening 508 toward the adhesive material 210 for reaction.

At operation 406, after the plasma is generated and flown toward the adhesive material 210, the adhesive material 210 may be chemically reacted with the plasma, forming residuals in volatile state, pumping out of the adhesive material removal apparatus 550. Furthermore, in some embodiments, a fluid wash process (e.g., suitable liquid precursors or gas precursors) to remove undesired precipitates, side product or residual adhesive materials, if any, from the photomask 202. During the fluid wash process, an ultrasonic or megasonic energy may be applied during the process to assist dislodging the precipitates, side product or residual adhesive materials, if any, from the photomask 202.

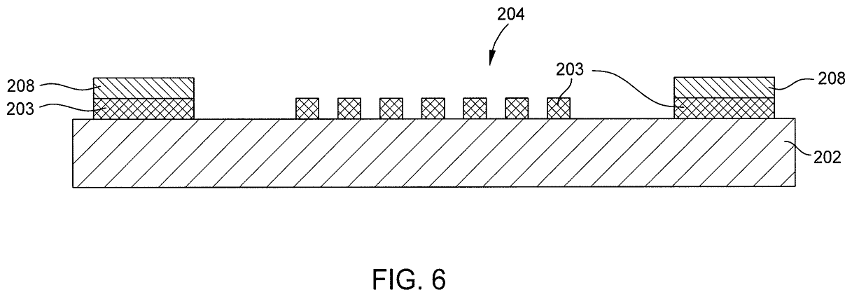

After adhesive material removal process, the adhesive material 210 is removed from the photomask 202, as shown in FIG. 6. Although only a lithography process is described in accordance with the present disclosure, embodiments of the present disclosure may be applied to any suitable process and in any suitable processing tools that requires removal an adhesive material of an attachment feature from an object.

Thus, embodiments of the present disclosure generally provide apparatus and methods for removing an adhesive material of an attachment feature from a photomask. The methods and apparatus advantageously removing the adhesive material from the photomask by a dielectric barrier discharge (DBD) plasma under a desired pressure range control. Accordingly, the method and the apparatus provided herein advantageously facilitate fabrication of photomasks which is suitable for utilization in lithography applications.

While the foregoing is directed to embodiments of the present disclosure, other and further embodiments of the disclosure may be devised without departing from the basic scope thereof, and the scope thereof is determined by the claims that follow.

What is claimed is:

1. An apparatus for processing a photomask, comprising:
an enclosure;
a substrate support assembly disposed in the enclosure; and
a dielectric barrier discharge (DBD) plasma generator disposed above the substrate support assembly, wherein the dielectric barrier discharge plasma generator further comprises:
a first electrode;
a second electrode, wherein the first and the second electrodes are vertically aligned and in parallel;
a dielectric barrier positioned between the first electrode and the second electrode; and
a discharge space defined between the dielectric barrier and the second electrode.

2. The apparatus of claim 1, wherein the dielectric barrier comprises a ceramic material or a polymer layer.

3. The apparatus of claim 1, wherein further comprises:
a discharge gas contained within the discharge space.

4. The apparatus of claim 3, wherein the discharge gas is selected from a group including oxygen gas (O₂), nitrogen gas (N₂), hydrogen gas (H₂), xenon gas (Xe), krypton gas (Kr), argon gas (Ar), neon gas (Ne) and helium gas (He).

5. The apparatus of claim 1, further comprising:
a gas inlet formed in the enclosure configured to supply a discharge gas to the discharge space.

6. The apparatus of claim 1, wherein the first and the second electrode has a rectangular configuration.

7. The apparatus of claim 1, further comprising:
a power supply coupled to the first and the second electrodes.

8. The apparatus of claim 1, further comprising:
an atmosphere control system coupled to the enclosure.

9. The apparatus of claim 7, wherein the dielectric barrier discharge (DBD) plasma generator generates a plasma in the discharge space toward a photomask when a power is supplied to the power supply.

10. The apparatus of claim 7, wherein the plasma reacts with an adhesive material on the photomask.

11. The apparatus of claim 1, wherein the dielectric barrier is fabricated from at least one of MgO, SiO₂, Y₂O₃, La₂O₃, CeO₂, SrO, CaO, MgF₂, LiF₂, and CaF₂.

12. The apparatus of claim 1, wherein the first and the second electrodes are fabricated from at least one of indium tin oxide (ITO), SnO₂, W, Mo, Cu, aluminum and alloys thereof.

13. The apparatus of claim 8, wherein the atmosphere control system maintains pressure within the enclosure at an ambient pressure.

14. The apparatus of claim 1, wherein the discharge space has a width between about 2 mm and about 30 mm.

15. A method for processing a photomask, comprising:
removing an adhesive material from a photomask by a plasma generated from a dielectric barrier discharge plasma generator.

16. A method for processing a photomask, comprising:
applying a power in a dielectric barrier discharge plasma generator disposed in an enclosure;
directing a discharge gas in a discharge space defined in the dielectric barrier plasma generator to a surface of a photomask disposed in a substrate support assembly in the enclosure;
generating a plasma in the discharge space toward the surface of the photomask; and
removing an adhesive material on the photomask.

17. The method of claim 16, wherein the generating the plasma further comprises:
maintaining a pressure of the enclosure at ambient pressure.

18. The method of claim 16, wherein the dielectric barrier discharge plasma generator further comprises:
providing a first electrode and a second electrode in the dielectric barrier discharge plasma generator;
disposing a dielectric barrier between the first and the second electrode and maintaining the first and the second electrode in a spaced-apart relation;
defining the discharge space between the dielectric barrier and the second electrode; and
supplying the discharge gas within the discharge space.

19. The method of claim 16, wherein the dielectric barrier discharge plasma generator has a configuration that allows the plasma generated in the discharge space to align with a location where the adhesive layer is formed on the photomask.

20. The method of claim 16, wherein the dielectric barrier comprises a ceramic material or a polymer layer.
